(19) United States
(12) Patent Application Publication
(10) Pub. No.: US 2008/0226839 A1
(43) Pub. Date: Sep. 18, 2008

(54) Surface treatment apparatus and surface treatment method

(75) Inventor: Shinsuke Seki, Chino (JP)

Correspondence Address: HARNESS, DICKEY & PIERCE, P.L.C., P.O. BOX 828, BLOOMFIELD HILLS, MI, 48303, US

(73) Assignee: Seiko Epson Corporation

(21) Appl. No.: 12/075,682

(22) Filed: Mar. 13, 2008

(30) Foreign Application Priority Data
Mar. 16, 2007 (JP) 2007-068537

(51) Int. Cl. C23C 16/48; C23C 16/00; H05H 1/24

(52) U.S. Cl. 427/569; 118/719; 427/255.11; 427/595

(57) ABSTRACT

A surface treatment apparatus includes: a vaporization device vaporizing a silane coupling agent, a treatment device in which a treatment object having an inorganic oriented film is arranged, into which the silane coupling agent that has been vaporized by the vaporization device is introduced, and which performs a surface treatment to the treatment object by subjecting the treatment object to the silane coupling agent; and a control device individually controlling a treatment atmosphere inside the vaporization device and a treatment atmosphere inside the treatment device.

### CROSS-REFERENCE TO RELATED APPLICATION

This application is based on and claims priority from Japanese Patent Application No. 2007-068537, filed on Mar. 16, 2007, the contents of which are incorporated herein by reference.

### BACKGROUND

1. Technical Field

The present invention relates to a surface treatment apparatus and a surface treatment method.

2. Related Art

For the method of manufacturing a liquid crystal device or the like, there has been conventionally proposed in the method of using an inorganic oriented film formed by an oblique evaporation process.

In the inorganic oriented film, it is known that electrically unstable defective portions are generated, and thus a high level of film quality cannot be obtained.

In the case where the electrically unstable defective portion exists, the defective portion may react with water, thereby forming a silanol group, which may lead to a poor display.

Regarding these problems, Japanese Unexamined Patent Application, First Publication No. 2007-25529 has proposed a technique in which a surface of a substrate having an inorganic oriented film formed thereon is subjected to a surface treatment by subjecting the substrate to a silane coupling agent, thereby reducing the reactivity of a silanol group.

On the other hand, as a method of subjecting a surface of a substrate to a surface treatment with the use of a silane coupling agent there have been proposed both a liquid phase treatment as disclosed in Japanese Unexamined Patent Application, First Publication No. 2007-25529 and a gas phase treatment as disclosed in Japanese Unexamined Patent Application, First Publication No. H5-220887.

The liquid phase treatment is a method for forming a film made from a silane coupling agent on a surge of a substrate, the method includes immersing the substrate in a solution of the silane coupling agent, and then taking out and drying the substrate.

By this liquid phase treatment, it is possible to carry out the surface treatment in a shorter period of time as compared to the gas phase treatment, but uniformity in the surface treatment is deteriorated as compared to the gas phase treatment.

The gas phase treatment is a method for forming a film made from a silane coupling agent on a surface of a substrate, by subjecting the substrate to an atmosphere in which the vaporized silane coupling agent is present.

By this gas phase treatment, it is possible to form a uniform film, that is to carry out a uniform surface treatment as compared to a liquid phase treatment but the treatment takes a longer period of time than for the liquid crystal treatment.

### SUMMARY

An advantage of some aspects of the invention is to provide a surface treatment apparatus and a surface treatment method, in which the surface of the treatment object having an inorganic oriented film is subjected to the surface treatment using a silane coupling agent, and in which the surface treatment is carried out in a short period of time with a high level of uniformity.

A first aspect of the invention provides a surface treatment apparatus including a vaporization device vaporizing a silane coupling agent; a treatment device in which a treatment object having an inorganic oriented film is arranged, into which the silane coupling agent that has been vaporized by the vaporization device is introduced, and which performs a surface treatment to the treatment object by subjecting the treatment object to the silane coupling agent; and a control device individually controlling a treatment atmosphere inside the vaporization device and a treatment atmosphere inside the treatment device.

According to the surface treatment apparatus of the invention, the treatment atmosphere inside the vaporization device and the treatment atmosphere inside the treatment device can be individually controlled by the control device.

Therefore, in the vaporization device, the atmosphere inside the vaporization device can be controlled so as to set the optimal conditions in which the silane coupling agent is desirably vaporized. Furthermore, in the treatment device, the atmosphere inside the treatment device can be controlled so as to set the optimal conditions in which the surface treatment is desirably performed using the gaseous silane coupling agent that has been vaporized by the vaporization device.

Therefore, it is possible to perform the surface treatment in a short period of time in addition to the merit of the conventional gas phase treatment in that the surface treatment is carried out with a high level of uniformity.

Therefore, according to the surface treatment apparatus of the invention, it is possible to perform the surface treatment in a short period of time with a high level of uniformity in the surface treatment apparatus in which the surface of the treatment object having the inorganic oriented film is subjected to the surface treatment using the silane coupling agent.

It is preferable that, in the surface treatment apparatus of the first aspect of the invention, the control device individually control the treatment atmosphere inside the vaporization device and the treatment atmosphere inside the treatment device by controlling at least one of temperature and inner pressure of the vaporization device and the treatment device.

By adopting the above constitution, the treatment atmosphere inside the vaporization device and the treatment atmosphere inside the treatment device are individually controlled by controlling at least one of temperature and inner pressure.

That is, at least one of temperature and inner pressure in the vaporization device and at least one of temperature and inner pressure in the treatment device are individually controlled.

Therefore, the treatment atmosphere inside the vaporization device and the treatment atmosphere inside the treatment device are individually controlled.

A second aspect of the invention provides a surface treatment method including vaporizing a silane coupling agent; and performing a surface treatment to a treatment object having an inorganic oriented film by subjecting the treatment object to the silane coupling agent that has been vaporized in the vaporization. In the surface treatment method, the treatment atmosphere in the vaporization of the silane coupling agent and the treatment atmosphere in the surface treatment are individually controlled.

According to the surface treatment method of the invention, it is possible to individually control the treatment atmosphere in the vaporization process and the treatment atmosphere in the surface treatment process.

Therefore, in the vaporization process, the atmosphere in the vaporization process can be controlled so as to set the optimal conditions in which the silane coupling agent is desirably vaporized. Furthermore, in the surface treatment process, the atmosphere in the surface treatment process can be controlled so as to set the optimal conditions in which the surface treatment is desirably performed using the gaseous silane coupling agent that has been vaporized in the vaporization process.

Therefore, it is possible to perform the surface treatment in a short period of time in addition to the merit of the conventional gas phase treatment in that the surface treatment is carried out with a high level of uniformity.

Therefore, according to the surface treatment method of the invention, it is possible to perform the surface treatment in a short period of time with a high level of uniformity in the surface treatment method in which the surface of the treatment object having the inorganic oriented film is subjected to the surface treatment using the silane coupling agent.

It is preferable that the surface treatment method of the second aspect of the invention further include performing a vacuum heating treatment in which the treatment object is heated in a vacuum atmosphere before performing the surge treatment.

By adopting the above method, hydroxyl group can be introduced to the surface of the object, prior to the surface treatment process.

Since the hydroxyl group facilitates the bonding of the silane coupling agent, it is possible to further shorten the time period of the surface treatment process.

Therefore, by adopting the above method, it is possible to perform the surface treatment with a high level of uniformity in a shorter period of time.

It is preferable that the surface treatment method of the second aspect of the invention further include performing an ultraviolet treatment in which the surface of the treatment object is subjected to ultraviolet rays before performing the surface treatment.

By adopting the above method, a hydroxyl group can be introduced to the surface of the object, prior to the surface treatment process.

Since the hydroxyl group facilitates the bonding of the silane coupling agent, it is possible to further shorten the time period of the surface treatment process.

Therefore, by adopting the above method, it is possible to perform the surface treatment with a high level of uniformity in a shorter period of time.

It is preferable that the surface treatment method of the second aspect of the invention further include performing a plasma treatment in which the surface of the treatment object is subjected to plasma before performing the surface treatment.

By adopting the above method, a hydroxyl group can be introduced to the surface of the object, prior to the surface treatment process.

Since the hydroxyl group facilitates the bonding of the silane coupling agent, it is possible to fierier shorten the time period of the surface treatment process.

Therefore, by adopting the above method, it is possible to perform the surface treatment with a high level of uniformity in a shorter period of time.

It is preferable that, in the surface treatment method of the second aspect of the invention, the following chemical formula (1) be used as the silane coupling agent.

ACₘH₂ₘSiOCₙH₂ₙ₊₁)₁ (1)

As the silane coupling agent of the invention, specifically, the above described chemical formula (1) can be used.

### BRIEF DESCRIPTION OF THE DRAWINGS

FIG. 1 is a schematic entire view showing constitution of a surface treatment apparatus according to an embodiment of the invention.

FIG. 2 is a table showing experimental examples of the apparatus for surface treatment according to one embodiment of the invention.

FIG. 3 is a view showing an equivalent circuit in a liquid crystal device.

FIG. 4 is an enlarged plan view showing a structure of pixel groups adjacent to each other in a TFT array substrate.

FIG. 5 is an enlarged cross-sectional view showing an element structure of the liquid crystal device.

FIG. 6 is an enlarged cross-sectional view showing a construction of a pixel region.

FIG. 7 is a view showing an example of a projection display device having a liquid crystal device.

### DESCRIPTION OF EXEMPLARY EMBODIMENTS

An embodiment of a surface treatment apparatus and a surface treatment method according to the invention will be described in detail hereinafter with reference to the drawings.

Herein, the scale of each member is appropriately adjusted in order to give a recognizable size in the following drawings.

Surface Treatment Apparatus and Surface Treatment Method

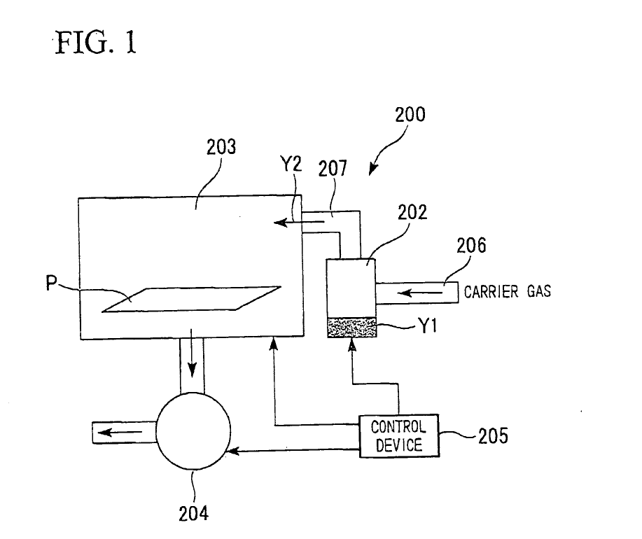

FIG. 1 shows a schematic entire constitution of the apparatus for surface treatment according to this embodiment.

As shown in FIG. 1, the surface treatment apparatus 200 of this embodiment performs a surface treatment of a substrate P that is an object (treatment object) to be treated having an inorganic oriented film formed thereon. The apparatus includes an evaporator 202 (vaporization device), a treatment device 203, a vacuum pump 204, and a control device 205.

The evaporator 202 vaporizes a silane coupling agent Y1 in a liquid state that is stored in the inside.

This evaporator 202 is connected with a carrier gas supply pipe 206 for supplying a carrier gas that is required to vaporize the silane coupling agent Y1 in the evaporator 202.

Furthermore, the evaporator 202 is connected to the treatment device 203 via a pipe 207.

In addition, the carrier gas is selected depending on the kinds of the silane coupling agent Y1 that are stored in the evaporator 202. As the carrier gas, for example, a nitrogen gas or an argon gas can be used.

Furthermore, the evaporator 202 includes a heater, a valve for adjusting pressure, and the like, which are not show in the figures.

The atmosphere inside the evaporator 202 is controlled by controlling the heater or the valve for adjusting pressure with the control device 205.

That is, the treatment atmosphere inside the evaporator 202 is controlled by the control device 205.

The substrate P having an inorganic oriented film formed thereon, as an treatment object, is arranged in the inside of the treatment device 203. Also, the vaporized silane coupling agent Y2 is introduced from the evaporator 202 to the treatment device 203 via the pipe 207.

In addition, the substrate P is supported by a supporting member that is not shown in the figures.

Furthermore, the treatment device 203 includes a heater, a valve for adjusting pressure, and the like, which are not shown in the figures.

The atmosphere inside the treatment device 203 is controlled by controlling the heater or the valve for adjusting pressure with the control device 205.

That is, the treatment atmosphere inside the treatment device 203 is controlled by the control device 205.

The treatment device 203 is connected with a vacuum pump 204 via a pipe 208.

The vacuum pump 204 is driven under the control by the control device 205 to discharge the inner air of the treatment device 203, and thus form a vacuum in the inside of the treatment device 203.

The control device 205 controls the evaporator 202, the treatment device 203, and the vacuum pump 204, as described above. The control device 205 is electrically connected to each of the evaporator 202, the treatment device 203, and the vacuum pump 204.

Furthermore, in the surface treatment apparatus 200 of this embodiment the control device 205 is capable of individually controlling the treatment atmosphere inside the evaporator 202 and the treatment atmosphere inside the treatment device 203.

More specifically, the control device 205 controls the treatment atmosphere inside the evaporator 202 by controlling the heater and the valve for adjusting the pressure of the evaporator 202, and controls the treatment atmosphere inside the treatment device 203 by controlling the heater and the valve for adjusting the pressure of the treatment device 203.

Furthermore, the control device 205 is capable of individually controlling the heater of the evaporator 202, the valve for adjusting the pressure of evaporator 202, the heater of the treatment device 203, and the valve for adjusting a pressure of the treatment device 203, and thus of individually controlling the treatment atmosphere inside the evaporator 202 and the treatment atmosphere inside the treatment device 203.

In the surface treatment apparatus 200 of this embodiment, the control device 205 controls the treatment atmosphere inside the evaporator 202 to be an optimal condition for vaporization of the silane coupling agent Y1, and controls the treatment atmosphere inside the treatment device 203 to be an optimal condition for surface treatment by the vaporized silane coupling agent Y2.

The optimal condition for vaporization of the silane coupling agent Y1 refers to a condition in which the silane coupling agent Y1 vaporizes in a shortest period of time.

That is, in the surface treatment apparatus 200 of this embodiment, the inner temperature and pressure of the evaporator 202 are controlled by the control device 205 to be the conditions under which the silane coupling agent Y1 is vaporized can be the shortest period of time.

Furthermore, the optimal condition for surface treatment by the vaporized silane coupling agent Y2 refers to a condition under which the surface treatment is completed in the shortest period of time.

Herein, completion of the surface treatment indicates that a film is made from a silane coupling agent to a predetermined film thickness on a surface of the substrate P.

That is, in the surface treatment apparatus 200 of this embodiment, the inner temperature and pressure of the treatment device 203 are controlled by the control device 205 to be the conditions under which a film is made from the silane coupling agent Y1 to a predetermined film thickness on a surface of the subsume P in the shortest period of time.

In addition, the surface treatment apparatus 200 of this embodiment is intended to carry out a surface treatment by subjecting a surface of the substrate P having an inorganic oriented film formed thereon to a silane coupling agent, thereby reducing the reactivity of a silanol group. As the silane coupling agent, those described in Japanese Unexamined Patent Application, First Publication No. 2007-25529 can be used.

That is, as the silane coupling agent Y1 that is stored in the evaporator 202, a silane coupling agent, the following chemical formula (1) can be used.

ACₘH₂ₘSiOCₙH₂ₙ₊₁)₁ (1)

More specifically, octadecyltriethoxysilane, tridecafluorooctyltrimethoxysilane, vinyltriethoxysilane, phenyltrimethoxysilane, N-phenyl-3-aminopropyltrimethoxysilane, p-stryltrimethoxysilane, p-trifluoromethylphenyltrimethoxysilane, 2-(3,4-epoxycyclohexyl)ethyltrimethoxysilane, and 3-glycidoxypropyltrimethoxysilane are preferably used.

Furthermore, as the silane coupling agent, octyltrimethoxysilane, glycidoxypropyltrimethoxysilane, tridecafluorotetrahydrooctyltriethoxysilane, and the like can also be used.

Next, the operation (surface treatment method) of the surface treatment apparatus 200 of this embodiment having the above-described constitution will be described.

First, the control device 205 controls the treatment atmosphere inside the evaporator 202 to be an optimal condition for vaporization of the silane coupling agent Y1.

Furthermore, the control device 205 controls the inside of the treatment device 203 to be a vacuum atmosphere by driving the vacuum pump 204, and controls the treatment atmosphere inside the treatment device 203 to be an optimal condition for surface treatment by the vaporized silane coupling agent Y2.

A carrier gas is supplied to the evaporator 202 via the carrier gas supply pipe 206, and the silane coupling agent Y1 vaporizes in the evaporator 202 (vaporization process).

The vaporized silane coupling agent Y2 is introduced to the treatment device 203 via the pipe 207.

By introducing the vaporized silane coupling agent Y2 to the treatment device 203, the inside of the treatment device 203 is filled with the silane coupling agent Y2.

Since the substrate P is arranged in the inside of the treatment device 203, the substrate P is subjected to the atmosphere in which the vaporized silane coupling agent Y2 is present.

As a result, a film made of the silane coupling agent is formed on a surface of the substrate P.

That is, a surface of the substrate P is treated with the silane coupling agent (surface treatment process).

As described above, by the surface treatment apparatus 200 of this embodiment, a treatment atmosphere in the vaporization process is controlled to be an optimal condition for vaporization of the silane coupling agent Y1, and a treatment atmosphere in the surface treatment process is controlled to be ant optimal condition for surface treatment with the vaporized silane coupling agent Y2.

That is, by the surface treatment apparatus 200 of this embodiment, the treatment atmosphere in the vaporization process and the treatment atmosphere in the surface treatment are individually controlled.

In addition, prior to the treatment processes (vaporization process and surface treatment process) in the surface treatment apparatus 200 of this embodiment, it is preferable to perform a vacuum heating treatment process for vacuum-heating the substrate P, an ultraviolet ray treatment process for treating a surface with an ultraviolet ray, or a plasma treatment process for treating a surface with plasma.

By performing such treatment processes, a hydroxyl group can be introduced to a surface of the treatment object, prior to the surface treatment process.

Since the hydroxyl group facilitates the bonding of the silane coupling agent, it is possible to shorten the time of the surface treatment process.

Accordingly, it is possible to carry out the surface treatment with a high level of uniformity in a shorter period of time.

As described above, according to the apparatus and the method for surface treatment of this embodiment, a treatment atmosphere during the vaporization of the silane coupling agent, and a treatment atmosphere during the surface treatment of the substrate P with the silane coupling agent, can be individually controlled.

In this manner, an optimal treatment atmosphere for vaporization of the silane coupling agent and an optimal treatment atmosphere for surface treatment with the silane coupling agent can be formed.

Accordingly, the surface treatment can be carried out in a short period of time, in addition to the advantage of the previously known gas phase treatment that a high level of uniformity in the surface treatment is provided.

Therefore, according to the apparatus and the method for surface treatment of this embodiment, it is possible to carry out the surface treatment with a high level of uniformity in a short period of time, in the surface treatment method in which a surface of the treatment object having an inorganic oriented film formed thereon is subject to surface treatment with a silane coupling agent.

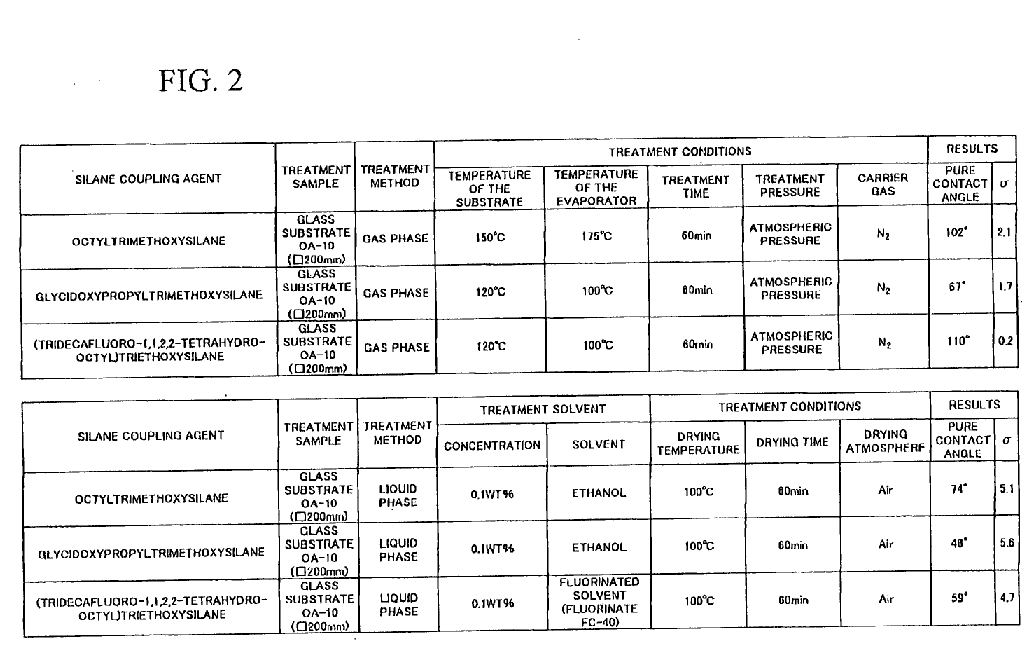

FIG. 2 shows experimental data illustrating the effects of the apparatus and the method for surface treatment of this embodiment.

In the present experiment, octyltrimethoxysilane, glycidoxypropyltrimethoxysilane, and tridecafluorotetrahydrooctyltriethoxysilane were used as the silane coupling agent, and a glass substrate was used as the object to be treated.

Herein, data from the surface treatment of a glass substrate with the above-mentioned silane coupling agent according to the apparatus and method for surface treatment of this embodiment, and data from the surface treatment of a glass substrate with the same silane coupling agent according to the known liquid phase treatment, were obtained.

According to the apparatus and the method for surface treatment of this embodiment, the pressure of each of the evaporator 202 and the treatment device 203 was controlled to be the atmospheric pressure, and a nitrogen gas was used as the carrier gas.

In the case of using octyltrimethoxysilane, the temperature of the evaporator 202 was controlled to be 175° C., and the temperature of the substrate (the temperature of the treatment device 203) was controlled to be 150° C.

In the case of using glycidoxypropyltrimethoxysilane, the temperature of the evaporator 202 was controlled to be 100° C., and the temperature of the substrate (the temperature of the treatment device 203) was controlled to be 120° C.

In the case of using tridecafluorotetrahydrooctyltriethoxysilane, the temperature of the evaporator 202 was controlled to be 100° C., and the temperature of the substrate (the temperature of the treatment device 203) was controlled to be 120° C.

In the conventional liquid phase treatment a concentration of the silane coupling agent solution was adjusted to 0.1 wt %, the atmosphere for the drying treatment was adjusted to the atmospheric atmosphere, and the temperature for the drying treatment was controlled to be 100° C.

In the case of using octyltrimethoxysilane, ethanol was used as the solvent.

In the case of using glycidoxypropyltrimethoxysilane, ethanol was used as the solvent.

In the case of using tridecafluorotetrahydrooctyltriethoxysilane, as the solvent, a fluorinated solvent (Fluorinate FC-40) was used.

Furthermore, in both the case of employing the apparatus and method for surface treatment of this embodiment, and the case of employing the conventional liquid phase treatment, after performing the surface treatment for 60 minutes in the same manner, pure contact angles at a plurality of portions on the glass substrate were obtained as data, respectively.

As a result, as shown in FIG. 2, according to the apparatus and method for surface treatment of this embodiment, when octyltrimethoxysilane was used, the average value and the standard deviation of the pure contact angles were 102° and 2.1, respectively.

In addition, according to the apparatus and method for surface treatment of this embodiment, when glycidoxypropyltrimethoxysilane was used, the average value and the standard deviation of the pure contact angles were 67° and 1.7, respectively.

Furthermore, according to the apparatus and method for surface treatment of this embodiment, when tridecafluorotetrahydrooctyltriethoxysilane was used, the average value and the standard deviation of the pure contact angles were 110° and 0.2, respectively.

On the other hand, according to the conventional liquid phase treatment, when octyltrimethoxysilane was used, the average value and the standard deviation of the pure contact angles were 74° and 5.1, respectively.

In addition, according to the conventional liquid phase treatment, when glycidoxypropyltriethoxysilane was used, the average value and the standard deviation of the pure contact angles were 46° and 5.6, respectively.

Furthermore, according to the conventional liquid phase treatment, when tridecafluorotetrahydrooctyltriethoxysilane was used, the average value and the standard deviation of the pure contact angles were 59° and 4.7, respectively.

As seen from the above-listed results, according to the apparatus and method for surface treatment of this embodiment, the surface treat it with a high level of uniformity can be accomplished with the same period of time as in the conventional liquid phase treatment.

Accordingly, according to the apparatus and method for surface treatment of this embodiment, it is possible to perform the surface treatment with a high level of uniformity in a short period of time.

Liquid Crystal Device

Next, a liquid crystal display including the substrate which is subjected to the surface treatment by the surface treatment apparatus of the above-described embodiment will be described.

The liquid crystal device described below is an active matrix transmission-type liquid crystal device in which TFT (Thin Film Transistor) elements are used as switching elements.

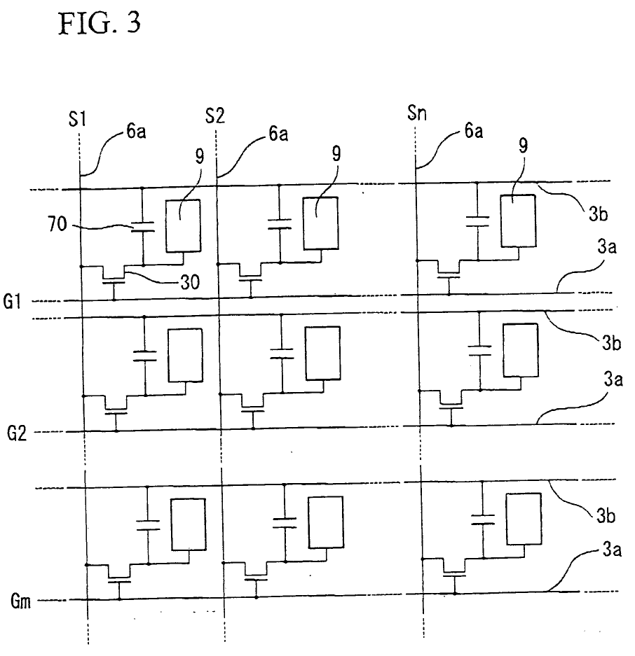

FIG. 3 shows an equivalent circuit of a switching element, a signal line, and the like in a plurality of pixels arranged in a grid-like arrangement (matrix formation) constructing an image display region of a transmission-type liquid crystal device of this embodiment.

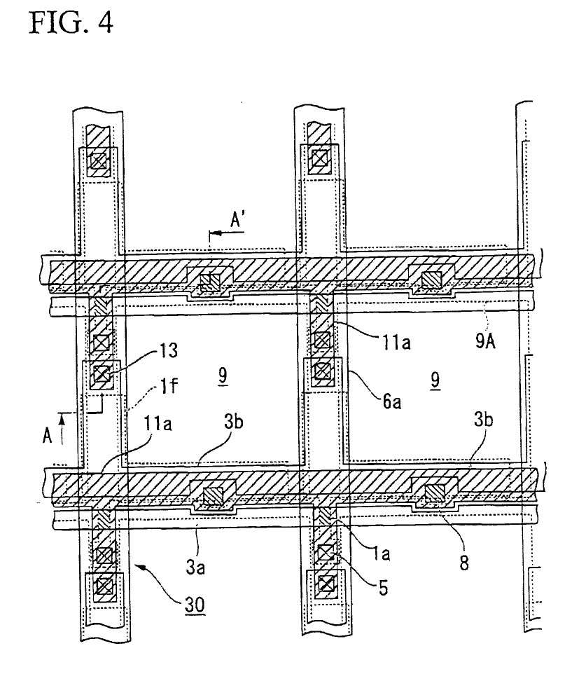

FIG. 4 shows an enlarged structure of a plurality of pixel groups adjacent to each other in a TFT (Thin Film Transistor) array substrate in which a data line, a scanning line, a pixel electrode, and the like are formed.

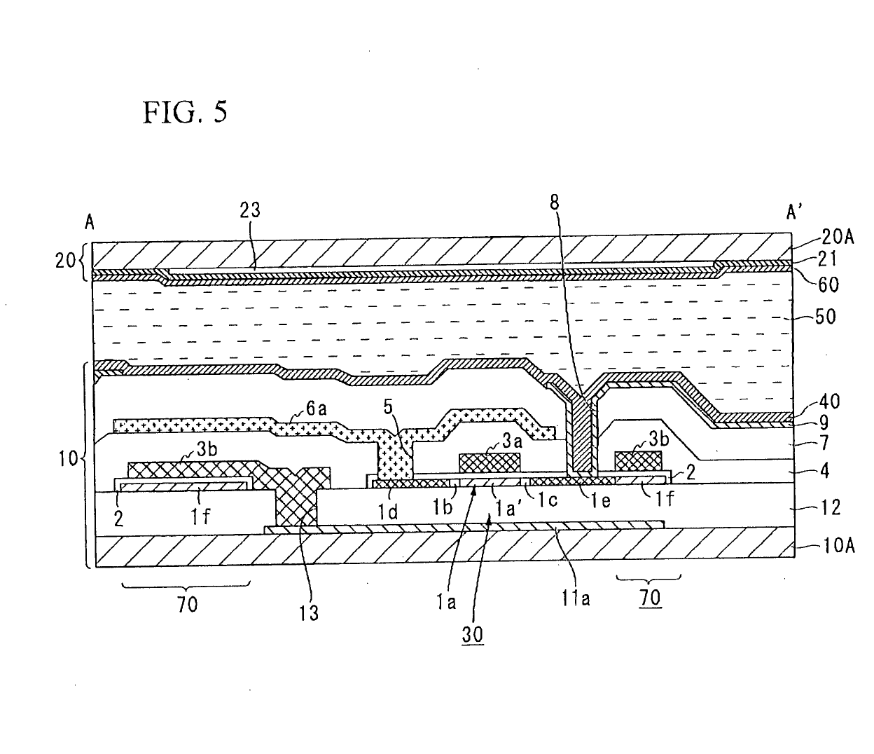

FIG. 5 is an enlarged cross-sectional view showing an element region for the transmission-type liquid crystal device of this embodiment, and is a cross-sectional view taken along the line A-A′ of FIG. 4.

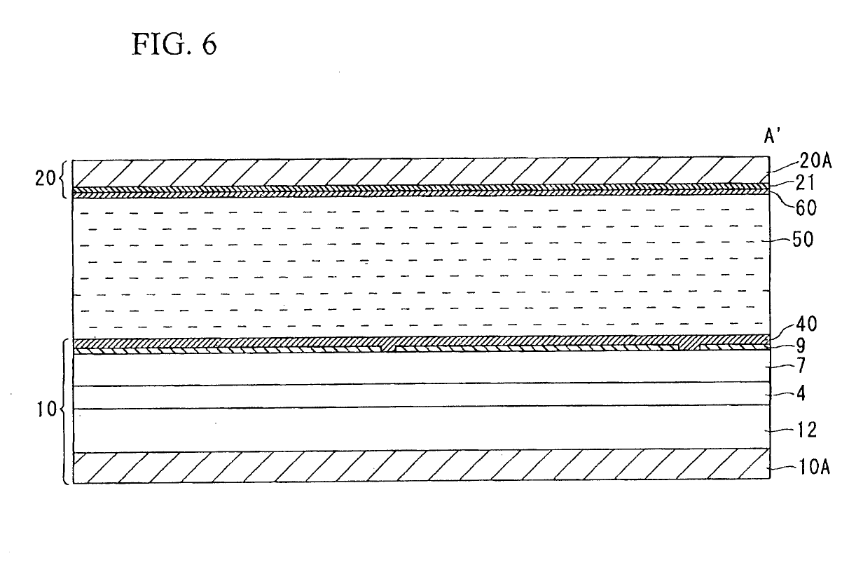

FIG. 6 is a cross-sectional view schematically showing a plurality of pixel regions for the transmission-type liquid crystal device of this embodiment.

In FIGS. 5 and 6, there is shown the case where the top side of the view is the side of light incidence, and the bottom side of the view is the observation side (observer side).

As shown in FIG. 3 in the transmission-type liquid crystal device of this embodiment, a pixel electrode 9 and a TFT element 30 serving as a switching element for controlling conductivity for the pixel electrode 9 are formed in a plurality of pixels arranged in the a grid-like arrangement (matrix formation) constructing an image display region, and a data line 6a from which an image signal is supplied is electrically connected to a source of the TFT element 30.

Image signals S1, S2, - - - , Sn written in data lines 6a are line-sequentially supplied in this order, or are supplied on a group basis for a plurality of data lines 6a adjacent to each other.

A scanning line 3a is electrically connected to a gate of the TFT element 30, scanning signals G1, G2, - - - , Gm for a plurality of scanning lines 3a are line-sequentially applied in pulses at a predetermined timing.

The pixel electrode 9 is electrically connected to a drain of the TFT element 30, and the TFT element 30 serving as the switching element are turned on during a given time. The image signals S1, S2, - - - . Sn supplied from the data lines 6a are written at a predetermined timing.

The image signals S1, S2, - - - , Sn at a predetermined level written in the liquid crystal through the pixel electrodes 9 are held for a given period between the pixel electrodes 9 and a common electrode described below.

The liquid crystal modulates the light and enables the gradation display by varying the orientation or order of the molecular aggregates according to the applied voltage level.

In order to prevent leakage of the held image signals, accumulative capacities 70 are added in parallel to liquid crystal capacities formed between the pixel electrodes 9 and the common electrode.

Next, a planar structure of the transmission-type liquid crystal device of this embodiment will be described with reference to FIG. 4.

As shown in FIG. 4, a plurality of rectangular pixel electrodes 9 (of which contours are shown by broken lines 9A) made of a transparent conductive material, such as Indium Tin Oxide (hereinafter, referred to as ITO), are provided in a grid-like arrangement on a TFT array substrate, and data lines 6a, the scanning lines 3a and capacity lines 3b are provided along vertical and horizontal boundaries of the pixel electrodes 9.

In this embodiment, regions where the pixel electrodes 9 and the data lines 6a, the scanning lines 3a, and the capacity lines 3b arranged to surround the pixel electrodes 9 are formed are pixels, and the pixels arranged in the a grid-like arrangement have a structure capable of performing a display.

The data lines 6a are electrically connected to a source region described below in a semiconductor layer 1a made of, for example, a polysilicon film, constructing the TFT elements 30 via a contact hole 5, and the pixel electrodes 9 are electrically connected to a drain region described below in the semiconductor layer 1a via a contact hole 8.

The scanning lines 3a are arranged to face a channel region described below in the semiconductor layer 1a (a region of oblique lines rising to the left in the figure), and the scanning lines 3a function as a gate electrode at a portion facing the channel region.

The capacity lines 3b have a main line part extending substantially linearly along the scanning line 3a (that is, as viewed in the vertical direction of the TFT array substrate, a first region formed along the scanning line 3a), and a projection portion projecting from a front stage side (upward in the figure) along the data line 6a from a point intersecting with the data line 6a (that is, as viewed in the vertical direction of the TFT array substrate, a second region provided extensively along the data line 6a).

In a region indicated by oblique lines rising to the right in FIG. 4, a plurality of first shading films 11a are provided.

Next, a cross-sectional structure of the transmission-type liquid crystal device of this embodiment will be described with reference to FIGS. 5 and 6.

In FIG. 6, some components such as switching elements and the like are omitted for visibility.

In the transmission-type liquid crystal device of this embodiment as shown in FIGS. 5 and 6, a liquid crystal layer 50 is interposed between a TFT array substrate 10 (substrate for a liquid crystal device) and a facing substrate 20 (substrate for a liquid crystal device) arranged facing the TFT array substrate 10.

The TFT array substrate 10 is mainly constructed with a substrate 10A made of a translucent material such as quartz or the like, a pixel electrode 9 formed on the surface of substrate 10A witch is close to the liquid crystal layer 50, and an oriented film 40. The facing substrate 20 is mainly constructed with a substrate 20A made of a translucent material such as glass, quartz, or the like, a common electrode 21 formed on the surface of substrate 20A witch is close to the liquid crystal layer 50, and an oriented film 60.

In the TFT array substrate 10 as shown in FIG. 5, the pixel electrode 9 is provided on the surface of substrate 10A witch is close to the liquid crystal layer 50, and at a position adjacent to each of the pixel electrode 9, a TFT element 30 for pixel switching which performs switching control over each pixel electrode 9 is provided.

The TFT element 30 for pixel switching has an LDD (Lilly Doped Drain) structure, and a scanning line 3a, a channel region 1a′ of the semiconductor layer 1a where a channel is formed by an electric field from the scanning line 3a, a gate insulating film 2 insulating the scanning line 3a and the semiconductor layer 1a, the data line 6a, a low-concentration source region 1b and a low-concentration drain region 1c of the semiconductor layer 1a, and a high-concentration source region 1d and a high-concentration drain region 1e of the semiconductor layer 1a.

On the substrate 10A including surfaces of the scanning line 3a and the gate insulating film 2, a second interlayer insulating film 4 is formed in which a contact hole 5 coupled to the high-concentration source region 1d and a contact hole 8 coupled to the high-concentration drain region 1e are opened.

In other words, the data line 6a is electrically connected to the high-concentration source region 1d via the contact hole 5 penetrating the second interlayer insulating film 4.

On the data line 6a and the second interlayer insulating film 4, a third interlayer insulating film 7 is formed in which the contact hole 8 coupled to the high-concentration drain region 1e is opened.

That is, the high-concentration drain region 1e is electrically connected to the pixel electrode 9 via the contact hole 8 penetrating the second interlayer insulating film 4 and the third interlayer insulating film 7.

In this embodiment, the gate insulating film 2 is extended from a position facing the scanning line 3a and is used as a dielectric film, and the semiconductor film 1a is extended to serve as a first accumulative capacity electrode 1f, and a part of the capacitance line 3b facing these serves as a second accumulative capacity electrode, thereby constructing an accumulative capacity 70.

In a region formed by each TFT element 30 for pixel switching on the surface of substrate 10A of TFT array substrate 10 which is close to the liquid crystal layer 50, the first shading film 11a is provided whereby return light that transits the TFT array substrate 10, that is reflected on the shown bottom surface of the TFT array substrate 10 (the boundary face of the TFT array substrate 10 and air), and that returns toward the liquid crystal layer 50 is prevented from entering at least the channel region 1a′ and the low-concentration source and drain regions 1b and 1c of the semiconductor layer 1a.

Between the first shading film 11a and the TFT element 30 for pixel switching, a first interlayer insulating film 12 is formed to electrically insulate the semiconductor layer 1a, constructing the TFT element 30 for pixel switching, from the first shading film 11a.

As shown in FIG. 4, the first shading film 11a is provided in the TFT array substrate 10 and also the first shading film 11a is constructed to be electrically connected to a front or rear stage capacity line 3b via a contact hole 13.

On the top surface of TFT array substrate 10 which is close to the liquid crystal layer 50, that is, the pixel electrode 9 and the third interlayer insulating film 7, an oriented film 40 (inorganic oriented film) is formed to control the orientation of liquid crystal molecules with the liquid crystal layer 50 at the non-voltage application time.

On the other hand, in regard to the facing substrate 20, on the surface of substrate 20A which is close to the liquid crystal layer 50, in a region facing a formation region of the data line 6a, the scanning line 3a and the TFT element 30 for pixel switching, that is, a region other than an opening region of each pixel section there is provided a second shading film 23 to prevent incident light from entering the channel region 1a′, the low-concentration source region 1b and the low-concentration drain region 1c of the semiconductor layer 1a of the TFT element 30 for pixel switching.

On the surface of substrate 20A which is close to the liquid crystal layer 50, on which the second shading film 23 is formed, the common electrode 21 made of ITO or the like is formed over substantially all the surface. In addition, on the surface which is closed to the liquid crystal layer 50, an oriented film 60 is formed to control the orientation of the liquid crystal molecules in the liquid crystal layer 50 at the non-voltage application time.

Herein, the TFT array substrate 10 and the facing substrate 20 which constitute the above-described liquid crystal device 100 are subjected to the surface treatment by the surface treatment apparatus and the surface treatment method of the above-described embodiment.

According to the surface treatment apparatus and the surface treatment method of the above described embodiment, it is possible to perform the surface treatment with a high level of uniformity in a short period of time, and thereby reduce the reactivity of a silanol group.

Therefore, the liquid crystal device having excellent display characteristics can be obtained.

The TFT array substrate 10 and the facing substrate 20 which have been subjected to the surface treatment by the surface treatment apparatus and the surface treatment method of the above-described embodiment are connected together via a sealing agent and additionally connecting a predetermined wiring after setting a liquid crystal panel by injecting the liquid crystal from a liquid crystal inlet formed on the sealing agent. The above-described liquid crystal device can thereby be manufactured.

Projection Display Device

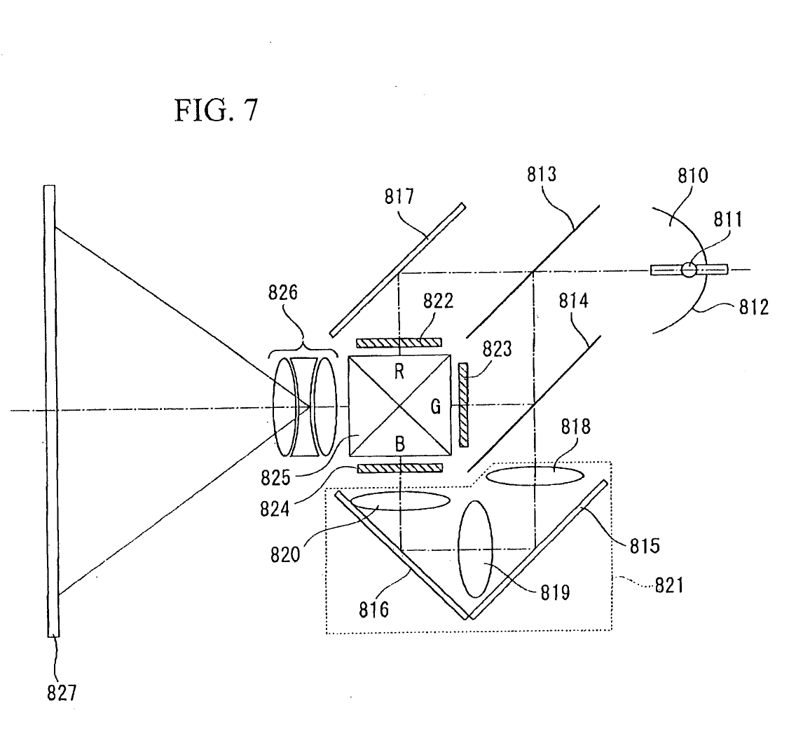

Next, a construction of a projection display device (projector) in which the liquid crystal device of the above-mentioned embodiment is provided as a light-modulation device will be described with reference to FIG. 7.

FIG. 7 is a schematic construction view showing main parts of the projection display device using the liquid crystal device of this embodiment as the light-modulation device.

In FIG. 7, reference numeral 810 is a light source, reference numerals 813 and 814 are dichroic mirrors, reference numerals 815, 816, and 817 are reflecting mirrors, reference numeral 818 is an entrance lens, reference numeral 819 is a relay lens reference numeral 820 is an exit lens, reference numerals 822, 823, and 824 are liquid crystal light-modulation devices, reference numeral 825 is a cross dichroic prism and reference numeral 826 is a projection lens.

The light source 810 includes a lamp 811 such as a metal halide lamp and a reflector 812 for reflecting light of the lamp.

The dichroic mirror 813 transmits red light of a light flux from the light source 810 and reflects blue light and green light.

The transmitted red light is reflected by the reflecting mirror 817 and enters the photo-modulation section 822 for red light having a liquid crystal device of an example of the above-described invention.

On the other hand, the green light of color lights reflected by the dichroic mirror 813 is reflected by the dichroic mirror 814 reflecting the green light and enters the light-modulation device 823 for green light having a liquid crystal device of an example of the above-described invention.

The blue light is transmitted through the second dichroic mirror 814.

A light-guiding section 821 is provided on the optical-path of the blue light.

The light-guiding section 821 constituted by a relay lens system including the entrance lens 818, the relay lens 819, and the exit lens 820 in order to compensate a difference from optical path lengths of green light and red light for blue light. The blue light is passed through the light-guiding section 821, and the blue light thereby enters the light-modulation device 824 for modulating the blue light. The light-modulation device 824 is a liquid crystal device of an example of the above-described invention.

The three color lights modulated by the light-modulation devices enter the cross dichroic prism 825.

The cross dichroic prism is formed by connecting four right-angle prisms, and on an inner face thereof, a dielectric multi-layer film for reflecting red light and a dielectric multi-layer film for reflecting blue light are formed so that these dielectric multi-layer films are across each other.

The three color lights are synthesized by the dielectric multi-layer films to form light expressing a color image.

The synthesized light is projected on a screen 827 by the projection lens 826 including the projection optical system.

The technical scope of the invention is not limited to the above embodiments, and various modifications can be made without deviating from the gist of the invention.

For example, the liquid crystal device provided with TFT as switching elements was described as an example in the embodiment, but this invention is also applied to a liquid crystal device provided with two-terminal elements, such as, thin film diodes, as switching elements.

The projection liquid crystal device was described as an example of the above-mentioned embodiment, but it is possible to apply a reflection-type liquid crystal device to this invention.

A liquid crystal device functioning in TN (Twisted Nematic) mode was described as an example in the embodiment, but it is also possible to apply this invention to a liquid crystal device functioning in VA (Vertical Alignment) mode.

A three-plate type projection display device (projector) was described as an example in the embodiment, but it is also possible to apply this invention to a single-plate type projection display device or a direct-view display device.

It is also possible to apply this invention to an electronic device other than the projector.

A portable telephone can be given as a specific example thereof.

The portable telephone is provided with a liquid crystal device relating to the above-mentioned embodiments or their modified examples in the display unit.

As other electronic devices, for example, IC cards, video cameras, PC computers, head-mount displays, fax devices with display functions, finders of digital cameras, portable TVs, DSP devices, PDAS, electronic notebooks, electric light notice boards, or displays for propagation and announcement, are given.

What is claimed is:

1. A surface treatment apparatus comprising:
a vaporization device vaporizing a silane coupling agent;
a treatment device in which a treatment object having an inorganic oriented film is arranged, into which the silane coupling agent that has been vaporized by the vaporization device is introduced, and which performs a surface treatment to the treatment object by subjecting the treatment object to the silane coupling agent; and
a control device individually controlling a treatment atmosphere inside the vaporization device and a treatment atmosphere inside the treatment device.

2. The surface treatment apparatus according to claim 1, wherein
the control device individually controls the treatment atmosphere inside the vaporization device and the treatment atmosphere inside the treatment device by controlling at least one of temperature and inner pressure of the vaporization device and the treatment device.

3. A surface treatment method comprising:
vaporizing a silane coupling agent; and
performing a surface treatment to a treatment object having an inorganic oriented film by subjecting the treatment object to the silane coupling agent that has been vaporized in the vaporization, wherein
the treatment atmosphere in the vaporization of the silane coupling agent and the treatment atmosphere in the surface treatment are individually controlled.

4. The surface treatment method according to claim 3, further comprising:
performing a vacuum heating treatment in which the treatment object is heated in a vacuum atmosphere before performing the surface treatment.

5. The surface treatment method according to claim 3, fierier comprising:
performing an ultraviolet treatment in which the surface of the treatment object is subjected to ultraviolet rays before performing the surface treatment.

6. The surface treatment method according to claim 3, further comprising:
performing a plasma treatment in which the surface of the treatment object is subjected to plasma before performing the surface treatment.

7. The surface treatment method according to claim 3, wherein
the following chemical formula (1) is used as the silane coupling agent.
ACₘH₂ₘSiOCₙH₂ₙ₊₁)₁ (1)
